(19) United States
(12) Patent Application Publication
(10) Pub. No.: US 2021/0234215 A1
(43) Pub. Date: Jul. 29, 2021

(54) COOLING SYSTEM

(71) Applicants: KABUSHIKI KAISHA TOSHIBA, Tokyo (JP); TOSHIBA ENERGY SYSTEMS & SOLUTIONS CORPORATION, Kawasaki-shi, Kanagawa (JP)

(72) Inventors: Takafumi NAKAHAMA, Fuchu Tokyo (JP); Masanori EGAWA, Shinagawa Tokyo (JP); Taihei KOYAMA, Tachikawa Tokyo (JP)

(73) Assignees: KABUSHIKI KAISHA TOSHIBA, Tokyo (JP); TOSHIBA ENERGY SYSTEMS & SOLUTIONS CORPORATION, Kawasaki-shi, Kanagawa (JP)

(21) Appl. No.: 15/734,570

(22) PCT Filed: Sep. 12, 2018
(86) PCT No.: PCT/JP2018/033865

§ 371 Date: Dec. 3, 2020

(30) Foreign Application Priority Data
Jun. 4, 2018 (JP) 2018-107171

(51) Int. Cl. H01M 10/6566; H05K 7/20; H01M 50/204; H01M 10/613; H01M 50/244; H01M 10/6563

(52) U.S. Cl. CPC H01M 10/6566; H05K 7/20136; H05K 7/20572; H01M 10/6563; H01M 10/613; H01M 50/244; H01M 50/204

(57) ABSTRACT

A cooling system of an embodiment includes a container having a first wall and a second wall intersecting the first wall; a housing accommodated in the container and including a plurality of racks juxtaposed to one another in a first direction being away from the first wall; a plurality of modules that generates heat, and is supported by the corresponding racks and placed in a row in a second direction intersecting the first direction and along the second wall; an opening through which air for cooling the modules flows into the container; and an air injection passage and an air discharge passage extending between the housing and the second wall and between the housing and an opposite side. The housing is provided with an intermediate passage extending between the injection passage and the discharge passage. The opening is juxtaposed to the injection passage in the second direction.

### CROSS-REFERENCE TO RELATED APPLICATIONS

This application is a national stage application of International Application No. PCT/JP2018/033865, filed Sep. 12, 2018, which designates the United States, and which claims the benefit of priority from Japanese Patent Application No. 2018-107171, filed Jun. 4, 2018, the entire contents of which are incorporated herein by reference.

### FIELD

Embodiments described herein relate generally to a cooling system.

### BACKGROUND

Conventionally, cooling systems have been known, which include a container; a housing contained in the container and provided with a plurality of racks; a plurality of heat-generating modules supported by the corresponding racks; and an opening through which air flows into the container to cool the modules.

In such a conventional cooling system, the opening and an injection passage inside the container are juxtaposed to each other in a first direction being away from the floor surface. The opening and the injection passage may be juxtaposed to each other in a second direction intersecting the first direction. In such a case, the opening, if located in the first direction of the housing, for example, may cause a circulatory flow in the injection passage.

It is preferable to provide such a cooling system with a novel, improved configuration and less inconvenience that can restrain occurrence of a circulatory flow in an injection passage.

### BRIEF DESCRIPTION OF DRAWINGS

FIG. 1 is an illustrative and schematic sectional view of a storage battery system including a cooling system according to a first embodiment, and a sectional view of FIG. 3 taken along the I-I line;

FIG. 2 is a sectional view of FIG. 1 taken along the II-II line;

FIG. 3 is a sectional view of FIG. 1 taken along the III-III line;

FIG. 4 is an illustrative and schematic sectional view of a storage battery system including a cooling system according to a second embodiment, and a sectional view of FIG. 6 taken along the IV-IV line;

FIG. 5 is a sectional view of FIG. 4 taken along the V-V line;

FIG. 6 is a sectional view of FIG. 4 taken along the VI-VI line;

FIG. 7 is an illustrative and schematic sectional view of a storage battery system including a cooling system according to a third embodiment, and a sectional view of FIG. 8 taken along the VII-VII line;

FIG. 8 is a sectional view of FIG. 7 taken along the VIII-VIII line;

FIG. 9 is an illustrative and schematic sectional view of a storage battery system according a first modification of the third embodiment;

FIG. 10 is an illustrative and schematic sectional view of a storage battery system according to a second modification of the third embodiment;

FIG. 11 is an illustrative and schematic sectional view of a storage battery system including a cooling system according to a fourth embodiment; and

FIG. 12 is an illustrative and schematic sectional view of a storage battery system according to a first modification of the fourth embodiment.

### DETAILED DESCRIPTION

According to one embodiment, in general, a cooling system includes a container, a housing, a plurality of modules, and an opening. The container has a first wall forming a floor surface, and a second wall intersecting the first wall. The housing is accommodated in the container and includes a plurality of racks placed in a row in a first direction being away from the floor surface. The plurality of modules generates heat, and is supported by the corresponding racks and placed in a row in a second direction. The second direction intersects the first direction and is along the second wall. Through the opening, air for cooling the modules flows into the container. One of spacing between the housing and the second wall and spacing between the housing and an opposite side relative to the second wall serves as an injection passage of the air that extends along the second wall. The other of the spacing between the housing and the second wall and the spacing between the housing and the opposite side relative to the second wall serves as a discharge passage of the air that extends along the second wall. The housing is provided with an intermediate passage that faces the plurality of modules and extends between the injection passage and the discharge passage. The opening is juxtaposed to the injection passage in the second direction, and extends between at least both ends of the housing in the first direction as viewed in the second direction.

The following will disclose exemplary embodiments of the present invention. Features of embodiments described below, and actions and effects produced by such features are merely exemplary. Throughout this disclosure, ordinal numbers are used to merely distinguish components, elements, parts, or members and are not intended to indicate order or priority.

Multiple embodiments disclosed below include same or like elements or components. Such elements or components are denoted by common reference numerals, and an overlapping description thereof will be omitted.

### First Embodiment

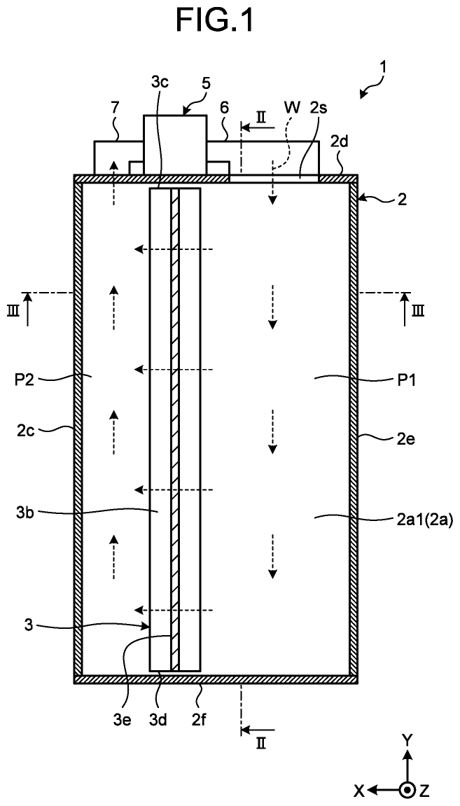

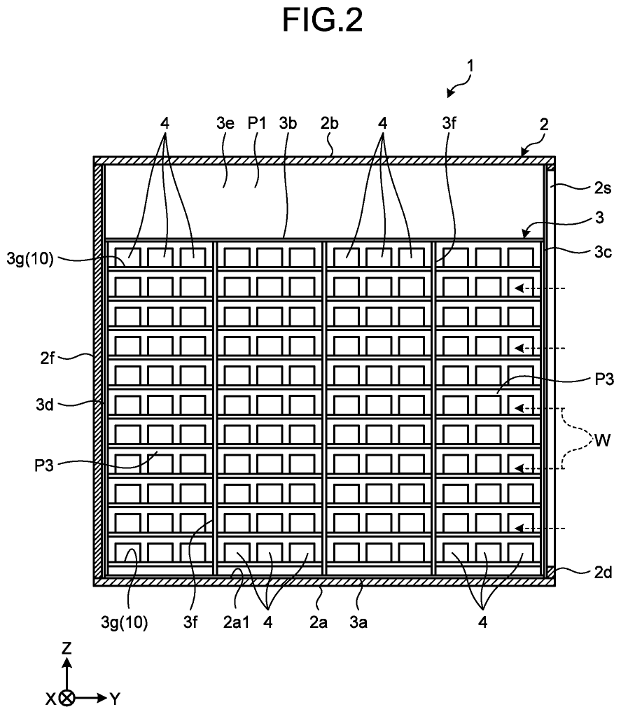

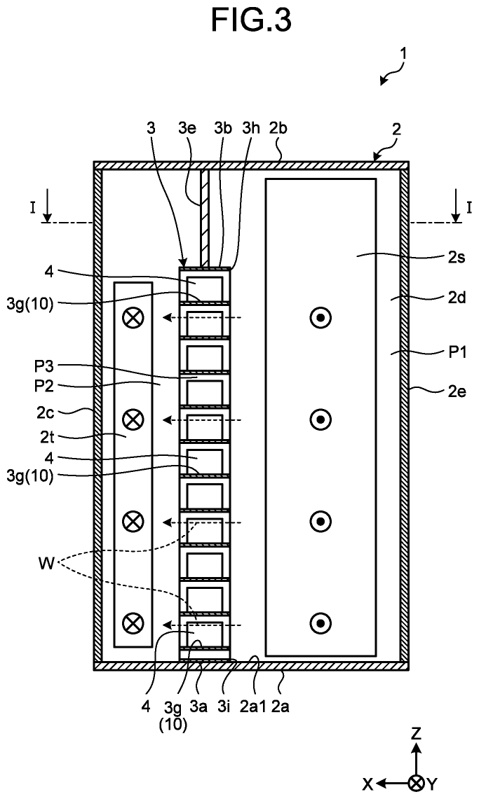

FIG. 1 is a sectional view of a storage battery system 1 including a cooling system and a sectional view of FIG. 3 taken along the I-I line. FIG. 2 is a sectional view of FIG. 1 taken along the II-II line. FIG. 3 is a sectional view of FIG. 1 taken along the III-III line. In the following, three directions perpendicular to one another are defined for the sake of convenience. X direction is along the short side (horizontal direction or width direction) of a container 2. Y direction is along the long side (front and rear direction) of the container 2. Z direction is along the height (vertical direction) of the container 2. In the following, the directions (indicated by X, Y, and Z arrows) are referred to as X direction, Y direction, and Z direction, respectively. The directions opposite to X direction, Y direction, and Z direction are referred to opposite X direction, opposite Y direction, and opposite Z direction.

As illustrated in FIGS. 1 to 3, the storage battery system 1 includes, for example, the container 2, a housing 3, a plurality of battery modules 4 (see FIGS. 2 and 3), and an air conditioning unit 5. The battery modules 4 are supported by racks 10 of the housing 3 and placed in a row with intervals in the Z direction and in the Y direction. The Z direction is an example of a first direction, and the Y direction is an example of a second direction. The battery modules 4 are an example of modules. The cooling system is not limited to this example and may be applied to, for example, a container-type data center accommodating a plurality of computers being modules set on the racks 10 in the housing 3.

As illustrated in FIG. 1, the air conditioning unit 5 is placed outside the container 2. An airflow W (cool air) is ejected from the air conditioning unit 5 and supplied to an injection passage P1 inside the container 2 through a duct 6. The airflow W then passes the racks 10 of the housing 3 across inside the container 2 in the X direction, is aggregated into a discharge passage P2, and discharged to the outside of the container 2. While passing through the housing 3, the airflow W exchanges heat with the battery modules 4 and returns to the air conditioning unit 5 through a duct 7 to be cooled by a heat exchanger. The cooled airflow W is then supplied into the container 2 again.

The housing 3 has, for example, a rectangular-parallelepiped shape shorter in length in the X direction. The housing 3 has a plurality of walls 3a to 3g. The wall 3a and the wall 3b (see FIG. 2) stand in parallel to each other with an interval in the Z direction, both extending in directions perpendicular to the Z direction (along an X-Y plane). The wall 3a is referred to as a bottom wall or a lower wall, and the wall 3b is referred to as a top wall or an upper wall, for instance. The wall 3a is supported by a floor surface 2a1 of the container 2, and the wall 3b faces the ceiling of the container 2 with an interval.

The wall 3c and the wall 3d stand in parallel to each other with an interval in the Y direction, both extending in directions perpendicular to the Y direction (along an X-Z plane). The wall 3c extends between Y-directional ends of the wall 3a and the wall 3b. The wall 3d extends between the opposite Y-directional ends of the wall 3a and the wall 3b. The walls 3c and 3d are also referred to as sidewalls or end walls, for instance.

The wall 3e projects from the wall 3b in the Z direction and extends in the Y direction. As illustrated in FIG. 1, the wall 3e is located in about a central part of the wall 3b in the X direction, and extends between the wall 3c and the wall 3d and between the wall 3b and the ceiling of the container 2. The wall 3e serves to partition the injection passage P1 and the discharge passage P2 inside the container 2 in the X direction. The wall 3e is also referred to as a partition wall, a dividing wall, or a separation wall.

It is preferable that the container 2 include a seal member for sealing a gap between the wall 3e and the container 2 and a gap between the walls 3c and 3d and the container 2 in order to prevent the airflow W from being discharged from the injection passage P1 to the discharge passage P2 without passing through the inside of the housing 3.

The walls 3g (see FIG. 2) are located between the wall 3a and the wall 3b, extending between the wall 3c and the wall 3d. In the housing 3 the walls 3g stand in parallel to one another with intervals in the Z direction. The walls 3g are parallel to the walls 3a and 3b. The walls 3g serve to partition the inside of the housing 3 into the racks 10 serving as a plurality of spaces (chambers) in the Z direction. The walls 3g are also referred to as shelf boards or partition walls, for example.

The walls 3f are located between the wall 3c and the wall 3d, extending between the wall 3a and the wall 3b. In the housing 3 the walls 3f stand in parallel to one another with intervals in the Y direction. The walls 3f are parallel to the walls 3c and 3d. The walls 3f serve to partition each of the racks 10 into a plurality of spaces (chambers) in the Y direction. Each of the racks 10 accommodates three battery modules 4 in a row in the Y direction, for example. The walls 3f are also referred to as dividing walls or separating walls, for example.

Each of the racks 10 is provided with an intermediate passage P3 to surround the battery modules 4. The intermediate passage P3 faces two or more battery modules 4 and extends between the injection passage P1 and the discharge passage P2 in the X direction. In the present embodiment, the housing 3 has no walls or members at the opposite ends in the X direction and is thus open. The housing 3 is not limited to this example. The housing 3 may have, for example, walls at the opposite ends in the X direction and these walls may be provided with openings to communicate with the racks 10. In such a case, each of the openings is preferably covered with a covering member such as a mesh or a filter. The housing 3 may be constituted of a plurality of members divisible in the Y direction. In this case, each of the walls 3f can include the wall 3c and the wall 3d of two divisible members placed on top of each other, for example. The housing 3 is also referred to as a rack housing or a battery rack, for example.

Each battery module 4 includes, for example, a module housing; a plurality of battery cells housed in the module housing; and an output terminal electrically connected to electrodes of the battery cells via an electroconductive member such as a bus bar. In the present embodiment, the output terminals of the battery modules 4 are connected together in series or in parallel to thereby form the container-type storage battery system 1. Such a container-type storage battery system 1 can be used in an outdoor facility or for an emergency power supply, for example. The battery module 4 is also referred to as a battery unit or a battery pack, and the battery cell is also referred to as a unit battery, for example.

Each battery cell can include, for example, a lithium-ion secondary battery. The battery cell may include another secondary battery, such as a nickel-hydrogen battery or a nickel-cadmium battery. A lithium-ion secondary battery is a non-aqueous electrolyte secondary battery containing lithium ions in an electrolyte serving as an electric conductor. Examples of a positive electrode material include a lithium-manganese composite oxide; a lithium-nickel composite oxide; a lithium-cobalt composite oxide; a lithium-nickel-cobalt composite oxide; a lithium-manganese-cobalt composite oxide; a spinel-type lithium-manganese-nickel composite oxide; and a lithium-phosphorus oxide having an olivine structure. Examples of a negative electrode material include oxide-based materials such as lithium titanate (LTO); and oxide materials such as a niobium composite oxide. Examples of the electrolyte (for example, an electrolysis solution) include organic solvents such as sole or a combination of ethylene carbonate, propylene carbonate, diethyl carbonate, ethyl methyl carbonate, and dimethyl carbonate, in which lithium salt such as fluorine-based complex salt (for example, LiBF4 or LiPF6) is blended.

As illustrated in FIG. 1, the container 2 has, for example, a rectangular-parallelepiped box shape longer in length in the Y direction. The container 2 has a plurality of walls 2a to 2f. The wall 2a and the wall 2b (see FIG. 2) are parallel to each other with an interval in the Z direction, both extending in directions perpendicular to the Z direction (along an X-Y plane). The wall 2a is referred to as a bottom wall or a lower wall, and the wall 2b is referred to as a top wall or an upper wall, for example. The wall 2a has a floor surface 2a1 that supports the housing 3. The wall 2a is an example of a first wall.

The wall 2c and the wall 2e (see FIG. 1) both extend in directions perpendicular to the X direction (on a Y-Z plane) and stand in parallel to each other with an interval in the X direction. The wall 2d and the wall 2f both extend in directions perpendicular to the Y direction (on an X-Z plane) and stand in parallel to each other with an interval in the Y direction. The walls 2c to 2f are also referred to as sidewalls or circumferential walls, for example.

Inside the container 2, there is a gap between the wall 2c and the housing 3 and the gap serves as the discharge passage P2. The discharge passage P2 extends along the wall 2c, that is, in the Y direction and the Z direction. The discharge passage P2 is connected to one end of the intermediate passage P3 in the X direction. In the discharge passage P2 the airflow W having exchanged heat with the battery modules 4 flows. The wall 2c is an example of a second wall.

Likewise, there is a gap between the housing 3 and a side opposite the wall 2c inside the container 2, that is, between the wall 2e and the housing 3. The gap serves as the injection passage P1. The injection passage P1 extends along the walls 2c and 2e, that is, in the Y direction and the Z direction. The injection passage P1 is connected to the other end of the intermediate passage P3 in the X direction. In the injection passage P1 the cool airflow W before heat exchange with the battery modules 4 flows.

The wall 2d is provided with a plurality of openings 2s and 2t (see FIG. 3). The opening 2t penetrates the wall 2d in the Y direction and extends long in the Z direction. In the present embodiment, the opening 2t is substantially the same in length as the housing 3 in the Z direction. The opening 2t faces the discharge passage P2, and the opening 2t and the discharge passage P2 are juxtaposed to each other in the Y direction.

The discharge passage P2 and the duct 7 of the air conditioning unit 5 communicate with each other via the opening 2t (see FIG. 1). In the present embodiment, the airflow W is suctioned by the fan of the air conditioning unit 5 from the discharge passage P2 into the duct 7 through the opening 2t. The opening 2t is an example of an air inlet of the air conditioning unit 5 and is an example of an air outlet of the container 2. The duct 7 is not limited to this example. For example, the opposite end of the duct 7 relative to the air conditioning unit 5 may be located inside the container 2. In this case, the opposite end of the duct 7 relative to the air conditioning unit 5 serves as the air inlet (container air outlet).

The opening 2s penetrates the wall 2d in the Y direction and extends in the Z direction and in the X direction. In the present embodiment, the opening 2s extends substantially entirely through the wall 2d in the Z direction. In other words, the opening 2s, as viewed in the Y direction (see FIG. 3), extends at least between one end 3h and the other end 3i of the housing 3 in the Z direction. The opening 2s faces the injection passage P1, and the opening 2s and the injection passage P1 are juxtaposed to each other in the Y direction.

The injection passage P1 and the duct 6 of the air conditioning unit 5 communicate with each other via the opening 2s (see FIG. 1). In the present embodiment, the airflow W is discharged from the duct 6 into the injection passage P1 through the opening 2s. The opening 2s is an example of an air outlet of the air conditioning unit 5 and is an example of an air inlet of the container 2. The duct 6 is not limited to this example. For example, the opposite end of the duct 6 relative to the air conditioning unit 5 may be located inside the container 2. In this case, the opposite end of the duct 6 relative to the air conditioning unit 5 serves as the air outlet (container air inlet).

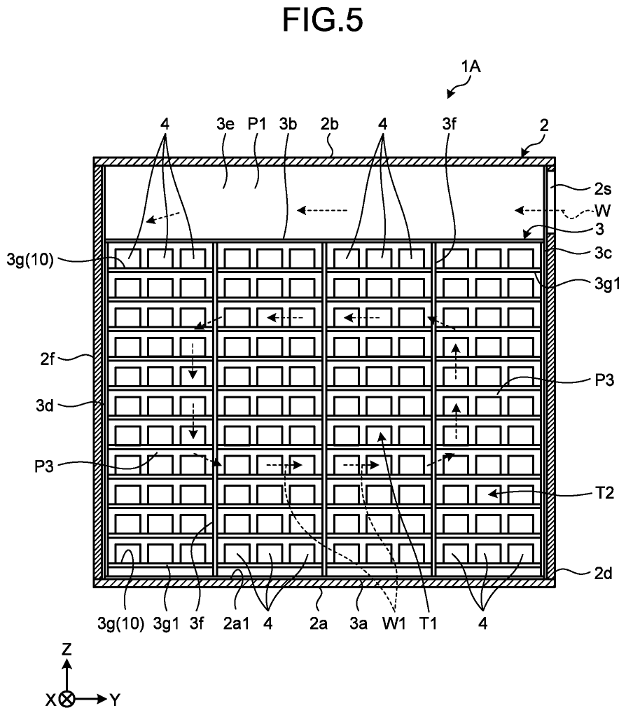

If the opening 2s is located only in the Z-direction of the housing 3, a circulatory flow W1 (see FIG. 5) around an X-axis may occur in a substantially central part of the injection passage P1. Such a circulatory flow W1 may form an air wall, for example, and the flow rate of the circulatory flow W1 may lower in an inner region T2 than in an outer region T1. As a result, the circulatory flow W1 may decrease in cooling performance for the battery modules 4 located in the inner region T1. In this regard, according to the present embodiment, the opening 2s extends between both ends 3h and 3i of the housing 3 in the Z direction, as viewed in the Y direction (see FIG. 3), making it possible to restrain occurrence of the circulatory flow W1 in the injection passage P1. This leads to, for example, reducing variations in cooling performance of the airflow W for the battery modules 4 and locational differences in temperature among the battery modules 4.

In the present embodiment, as described above, the injection passage P1 of the airflow W extends along the wall 2c between the housing 3 and the side opposite the wall 2c (second wall), and the discharge passage P2 of the airflow W extends along the wall 2c between the housing 3 and the wall 2c, by way of example. The housing 3 is provided with the intermediate passage P3 facing the battery modules 4 and extending between the injection passage P1 and the discharge passage P2. The opening 2s is juxtaposed to the injection passage P1 in the Y direction, extending at least between both Z-direction ends 3h and 3i of the housing 3, as viewed in the Y direction. According to such a configuration, for example, the opening 2s can work to restrain occurrence of the circulatory flow W1 in the injection passage P1. This makes it possible to reduce locational differences in temperature among the battery modules 4, and elongate the lifespan of the storage battery system 1, for example.

### Second Embodiment

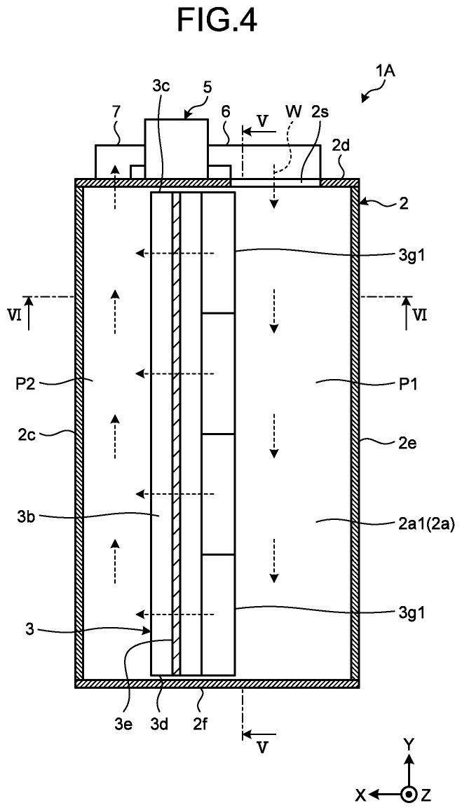

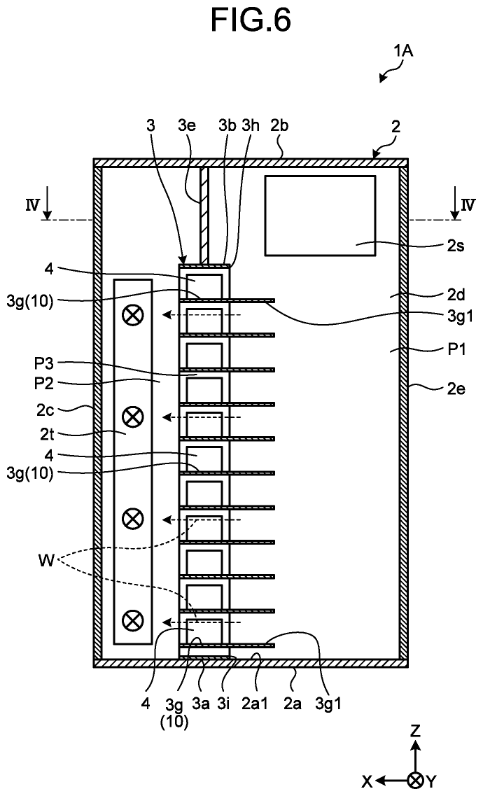

FIG. 4 is a sectional view of a storage battery system 1A and a sectional view of FIG. 6 taken along the IV-IV line. FIG. 5 is a sectional view of FIG. 4 taken along the V-V line. FIG. 6 is a sectional view of FIG. 4 taken along the VI-VI line. The storage battery system 1A of an embodiment as illustrated in FIGS. 4 to 6 has same or similar features as the storage battery system 1 of the first embodiment. Thus, the present embodiment can also produce the same or similar effects based on the same or similar features as the first embodiment.

However, the present embodiment differs from the first embodiment, for example, in that each of the walls 3g (shelf boards) of the housing 3 includes a projection 3g1 as illustrated in FIGS. 4 to 6. The projection 3g1 projects into the injection passage P1 from the opposite X-directional end of the wall 3g and extends in the Y direction. The housing 3 is provided with a plurality of projections 3g1 parallel to one another with intervals in the Z direction.

The projections 3g1 at least partially overlap the opening 2s in the Z direction, as viewed in the Y direction (see FIG. 6), for example. The projections 3g1 are an example of a first projection and are also referred to as extensions or overhangs. In the present embodiment, the opening 2s (see FIGS. 5 and 6) is located in the Z-direction of the housing 3. This arrangement may cause occurrence of the circulatory flow W1 around the X-axis in the injection passage P1.

In the present embodiment, however, the housing 3 is provided with the projections 3g1 that serve to divide the circulatory flow W1, if occurs, in the Z direction in the injection passage P1, to be able to restrain the circulatory flow W1, for example. This results in decreasing locational differences in temperature among the battery modules 4, which can elongate the lifespan of the storage battery system 1A.

The storage battery system 1A includes, for example, other modules such as contactors in addition to the battery modules 4. In such a case, it is preferable, for example, to set other modules in a part of the housing 3 corresponding to the inner region T1 of the circulatory flow W1 and set the battery modules 4 in a part corresponding to the outer region T2 of the circulatory flow W1. This arrangement makes it possible to further reduce differences in temperature among the battery modules 4.

### Third Embodiment

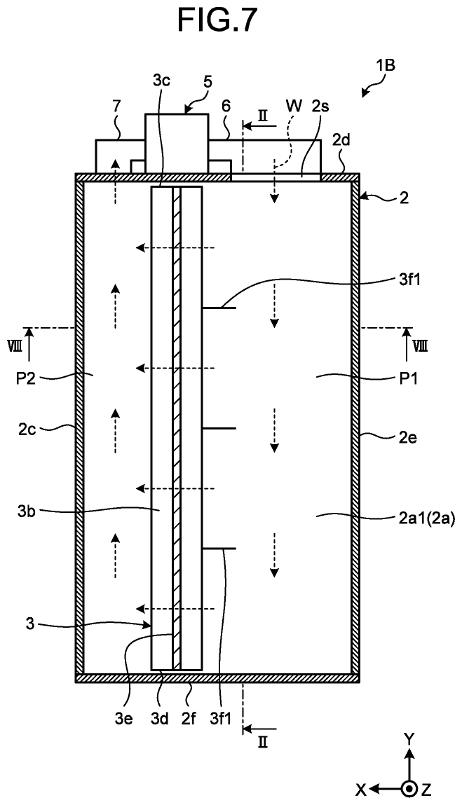

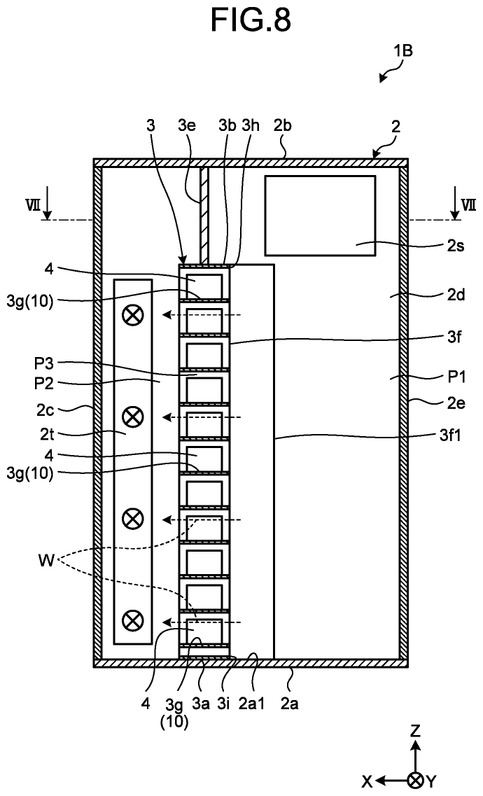

FIG. 7 is a sectional view of a storage battery system 1B and a sectional view of FIG. 8 taken along the VII-VII line. FIG. 8 is a sectional view of FIG. 7 taken along the VIII-VIII line. The storage battery system 1B of an embodiment as illustrated in FIGS. 7 and 8 has the same or similar features as the storage battery system 1 of the first embodiment. Thus, the present embodiment can also produce the same or similar effects based on the same or similar features as the first embodiment.

However, the present embodiment differs from the first embodiment in that each of the walls 3f of the housing 3 includes a projection 3f1, for example, as illustrated in FIGS. 7 and 8. The projection 3f1 projects into the injection passage P1 from the opposite X-directional end of the wall 3f and extends in the Z direction. The housing 3 is provided with the projections 3f1 parallel to one another with intervals in the Y direction.

As viewed in the Y direction (see FIG. 8), the projections 3f1 at least partially overlap the opening 2s in the Z direction, for example. The projections 3f1 are an example of a second projection and are also referred to as extensions or overhangs.

Thus, in the present embodiment, the housing 3 is provided with the projections 3f1 that serve to divide the circulatory flow W1, if occurs, in the Y direction in the injection passage P1, for example, to be able to restrain the circulatory flow W1 (see FIG. 5). This leads to, for example, decreasing locational differences in temperature among the battery modules 4, enabling elongation of the lifespan of the storage battery system 1B.

### First Modification of Third Embodiment

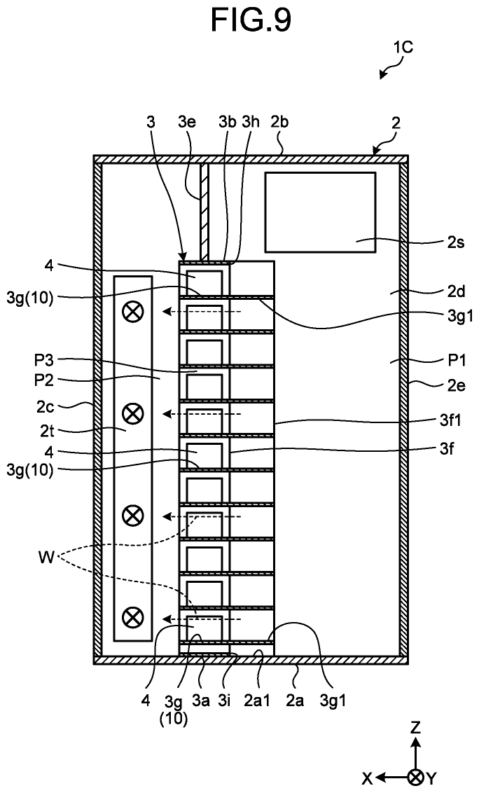

FIG. 9 is an illustrative and schematic sectional view of a first modification of the storage battery system 1B. A storage battery system 1C of the first modification illustrated in FIG. 9 has the same or similar features as the storage battery system 1B of the third embodiment. Thus, the present modification can also produce the same or similar effects based on the same or similar features as the third embodiment.

However, the present modification differs from the third embodiment in that the housing 3 is provided with the projections 3g1 and the projections 3f1, for example, as illustrated in FIG. 9. The projections 3g1 are an example of a first projection, and the projection 3f1 are an example of a second projection. Thus, in the present modification, the housing 3 is provided with the projections 3g1 and 3f1 which serve to divide the circulatory flow W1 (see FIG. 5), if occurs, in the Z direction and in the Y direction in the injection passage P1, for example, to be able to restrain the circulatory flow W1. This leads to, for example, further decreasing locational differences in temperature among the battery modules 4.

### Second Modification of Third Embodiment

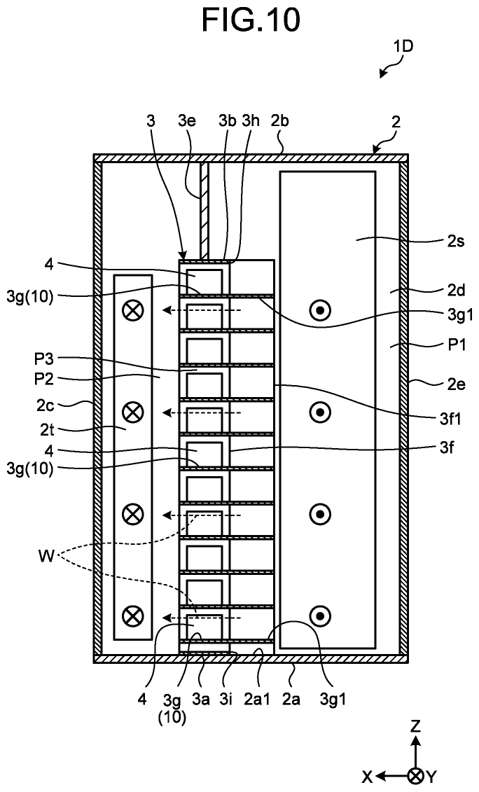

FIG. 10 is an illustrative and schematic sectional view of a second modification of the storage battery system 1B. A storage battery system 1D of the modification illustrated in FIG. 10 has the same or similar features as the storage battery system 1B of the third embodiment. Thus, the present modification can also produce the same or similar effects based on the same or similar features as the third embodiment.

However, the present modification differs from the third embodiment, for example, as illustrated in FIG. 10 in that the housing 3 is provided with the projections 3g1 and projections 3f1 and in that the opening 2s extends between both Z-directional ends 3h and end 3i of the housing 3, as viewed in the Y direction. In the present modification, the projections 3g1 and 3f1 do not overlap with the opening 2s in the Y direction, but are offset from the opening 2s in the X direction. However, this example is not limiting and at least part of the projections 3g1 and 3f1 may overlap the opening 2s in the Y direction. In the present modification, the housing 3 includes both the projections 3g1 and 3f1, however, the housing 3 is not limited to this example. The housing 3 may include either the projections 3g1 or the projections 3f1 (for example, the projections 3g1). Thus, according to the present modification, the opening 2s and the projections 3g1 and 3f1 work to restrain the circulatory flow W1, if occurs, in the injection passage P1. This leads to, for example, ensuring decrease in locational differences in temperature among the battery modules 4.

### Fourth Embodiment

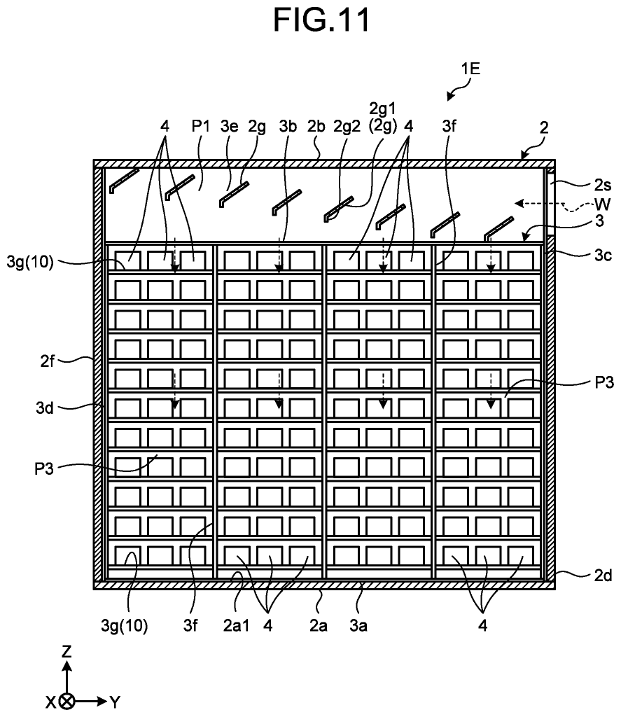

FIG. 11 is a sectional view of a storage battery system 1E. The storage battery system 1E of an embodiment illustrated in FIG. 11 has the same or similar features as the storage battery system 1 of the first embodiment. Thus, the present embodiment can also produce the same or similar effects based on the same or similar features as the first embodiment.

However, the present embodiment differs from the first embodiment in including a plurality of guide plates 2g in the injection passage P1, for example, as illustrated in FIG. 11. The guide plates 2g and the opening 2s are located in the Z direction of the housing 3 and are lined up in the Y direction. In addition, the guide plates 2g are partially offset from one another such that the guide plates 2g are further oriented in the Z direction as being away from the opening 2s. The guide plates 2g are supported by, for example, the wall 2e (see FIG. 1) of the container 2 and the wall 3e or by the wall 2b (ceiling) of the container 2.

Each of the guide plates 2g has, for example, a sloping surface 2g1 and a vertical surface 2g2. The sloping surface 2g1 is inclined toward the floor surface 2a1 (housing 3) as being away from the opening 2s, that is, further oriented in the opposite Y direction. The vertical surface 2g2 extends in the opposite Z direction (downward) from an end of the sloping surface 2g1 in the opposite Y direction. The guide plates 2g function to deflect the airflow having flowed into the injection passage P1 from the opening 2s and guide the airflow toward the floor surface 2a1 (housing 3). The guide plates 2g are also referred to as airflow deflector plates, for example.

Thus, in the present embodiment, the guide plates 2g located in the injection passage P1 serve to restrain occurrence of the circulatory flow W1 (see FIG. 5) in the injection passage P1 by, for example, guiding the airflow W toward the housing 3. This leads to, for example, reducing locational differences in temperature among the battery modules 4, enabling elongation of the lifespan of the storage battery system 1E.

### First Modification of Fourth Embodiment

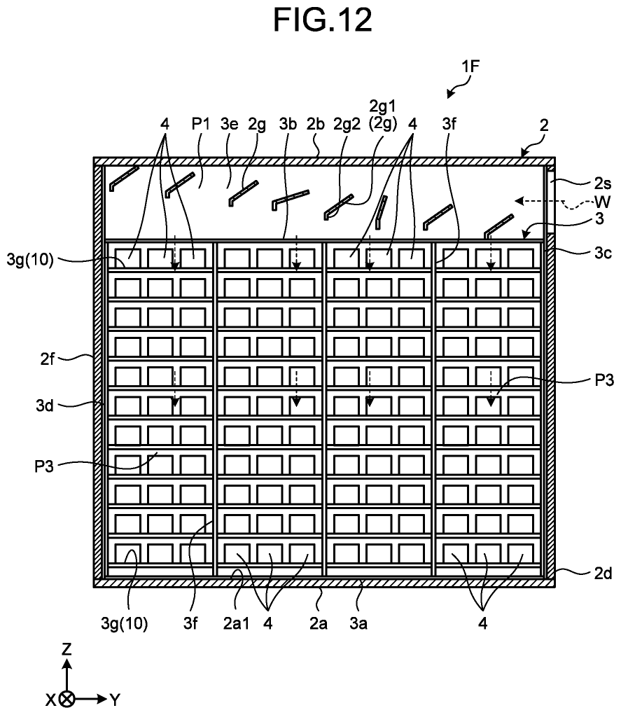

FIG. 12 is an illustrative and schematic sectional view of a first modification of the storage battery system 1E. A storage battery system 1F of the modification illustrated in FIG. 12 has the same or similar features as the storage battery system 1E of the fourth embodiment. Thus, the present modification can also produce the same or similar effects based on the same or similar features as the fourth embodiment.

However, the present modification differs from the fourth embodiment, for example, in that the guide plates 2g are placed at a higher density in the central part of the injection passage P1 than in both Y-direction ends thereof, as illustrated in FIG. 12. In the present modification, the spacing between the Z-directional ends of the two adjacent guide plates 2g in the Y direction is narrower in the central part than at both Y-directional ends. The airflow W, flowing from the opening 2s, may increase in velocity in the central part and decrease at both ends in the Y direction. In view of this, according to the present modification the guide plates 2g are disposed in the central part at a higher density in the Y direction to increase resistance, thereby allowing the airflow W to flow in the opposite Z direction (downward) at a constant velocity. It is preferable to set the spacing between the Z-directional ends of the guide plates 2g in the central part in the Y direction to the same pitch as the rest of the plates, in order to enhance the uniformity of the flow velocity. According to the present modification, thus, the guide plates 2g work to reduce variations in cooling performance of the airflow W for the battery modules 4, for example, resulting in decreasing locational differences in temperature among the battery modules 4.

While certain embodiments of the present invention have been described, these embodiments have been presented by way of example only, and are not intended to limit the scope of the inventions. These novel embodiments may be embodied in a variety of other forms, and various omissions, substitutions, combinations and changes may be made without departing from the spirit of the inventions. The accompanying claims and their equivalents are intended to cover these embodiments or modifications thereof as would fall within the scope and spirit of the inventions. The present invention can be implemented by structures and configurations other than those disclosed in the above embodiments and attain various effects (including derivative effects) based on the basic structures and configurations (technical features). Furthermore, specifications (such as structure, kind, orientation, shape, size, length, width, thickness, height, number, layout, position, and material) of the respective constituent elements can be modified as appropriate.

1. A cooling system comprising:
a container having a first wall and a second wall intersecting the first wall, the first wall forming a floor surface;
a housing accommodated in the container and comprising a plurality of racks placed in a row in a first direction being away from the floor surface;
a plurality of modules that generates heat, and is supported by the corresponding racks and placed in a row in a second direction, the second direction intersecting the first direction and being along the second wall; and
an opening through which air for cooling the modules flows into the container, wherein
one of spacing between the housing and the second wall and spacing between the housing and an opposite side relative to the second wall serves as an injection passage of the air that extends along the second wall, and
the other of the spacing between the housing and the second wall and the spacing between the housing and the opposite side relative to the second wall serves as a discharge passage of the air that extends along the second wall,
the housing is provided with an intermediate passage that faces the plurality of modules and extends between the injection passage and the discharge passage, and
the opening is juxtaposed to the injection passage in the second direction, and extends between at least both ends of the housing in the first direction as viewed in the second direction.

2. The cooling system according to claim 1, wherein
the housing includes at least one of:
a first projection that projects from the housing into the injection passage and extends in the second direction, and
a second projection that projects from the housing into the injection passage and extends in the first direction.

3. A cooling system comprising:
a container having a first wall and a second wall intersecting the first wall, the first wall forming a floor surface;
a housing accommodated in the container and comprising a plurality of racks placed in a row in a first direction being away from the floor surface;
a plurality of modules that generates heat, and is supported by the corresponding racks and placed in a row in a second direction, the second direction intersecting the first direction and being along the second wall; and
an opening through which air for cooling the modules flows into the container, wherein
one of spacing between the housing and the second wall and spacing between the housing and an opposite side relative to the second wall serves as an injection passage of the air that extends along the second wall, and
the other of the spacing between the housing and the second wall and the spacing between the housing and the opposite side relative to the second wall serves as a discharge passage of the air that extends along the second wall,
the housing is provided with an intermediate passage that faces the plurality of modules and extends between the injection passage and the discharge passage, and
the opening is juxtaposed to the injection passage in the second direction, and
the housing includes at least one of:
a first projection that projects from the housing into the injection passage and extends in the second direction, and
a second projection that projects from the housing into the injection passage and extends in the first direction.

4. A cooling system comprising:
a container having a first wall and a second wall intersecting the first wall, the first wall forming a floor surface;
a housing accommodated in the container and comprising a plurality of racks placed in a row in a first direction being away from the floor surface;
a plurality of modules that generates heat, and is supported by the corresponding racks and placed in a row in a second direction, the second direction intersecting the first direction and being along the second wall; and
an opening through which air for cooling the modules flows into the container, wherein
one of spacing between the housing and the second wall and spacing between the housing and an opposite side relative to the second wall serves as an injection passage of the air that extends along the second wall, and
the other of the spacing between the housing and the second wall and the spacing between the housing and the opposite side relative to the second wall serves as a discharge passage of the air that extends along the second wall,
the housing is provided with an intermediate passage that faces the plurality of modules and extends between the injection passage and the discharge passage, and
the opening is juxtaposed to the injection passage in the second direction and located in the first direction of the housing, and
the injection passage is provided with a plurality of guide plates that is placed in a row with intervals in the second direction to guide, toward the housing, the air having flowed from the opening.
